(19) United States
(12) Patent Application Publication
(10) Pub. No.: US 2014/0069802 A1
(43) Pub. Date: Mar. 13, 2014

(54) APPARATUS AND METHODS FOR PHYSICAL VAPOR DEPOSITION

(71) Applicants: Paul Yih, Jhubei City (TW); Wen-I Hsieh, Hsinchu City (TW); Cheng-Pin Yang, Zhongli City (TW); Chuan-Yi Chen, New Taipei City (TW); Chih-Ping Huang, New Taipei City (TW); Tien-Peng Chen, Longtan Township (TW); Jui-Chih Liao, Chia-yi City (TW); Shih-Lun Huang, Pingzhen City (TW)

(72) Inventors: Paul Yih, Jhubei City (TW); Wen-I Hsieh, Hsinchu City (TW); Cheng-Pin Yang, Zhongli City (TW); Chuan-Yi Chen, New Taipei City (TW); Chih-Ping Huang, New Taipei City (TW); Tien-Peng Chen, Longtan Township (TW); Jui-Chih Liao, Chia-yi City (TW); Shih-Lun Huang, Pingzhen City (TW)

(73) Assignee: QUALCOMM MEMS Technologies, Inc., San Diego, CA (US)

(21) Appl. No.: 13/609,076

(22) Filed: Sep. 10, 2012

(51) Int. Cl. C23C 14/35

(52) U.S. Cl. 204/192.12; 204/298.16

(57) ABSTRACT

This disclosure provides systems, methods, and apparatus related to physical vapor deposition. In one aspect, an apparatus includes a magnet assembly including a magnet element, a substrate holder configured to hold a substrate, a target holder configured to hold a target positioned between the magnet assembly and the substrate, a motor configured to move the magnet assembly across a face of the substrate, and a controller. The controller includes program instructions for conducting a process including moving the magnet assembly across the face of the substrate using the motor to sputter material from the target onto the substrate. The material sputtered onto the substrate may have a substantially uniform thickness.

### TECHNICAL FIELD

This disclosure relates generally to physical vapor deposition and more particularly to apparatus and methods for depositing a uniform-thickness material with physical vapor deposition.

### DESCRIPTION OF THE RELATED TECHNOLOGY

Electromechanical systems (EMS) include devices having electrical and mechanical elements, actuators, transducers, sensors, optical components (such as mirrors and optical film layers) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

In manufacturing processes for MEMS devices, including IMOD devices, layers of material may be deposited using different techniques. One material deposition technique is physical vapor deposition (PVD), which includes sputter deposition or sputtering. In sputtering, material may be ejected from a target or a source by a plasma, with the ejected material depositing onto a substrate, forming a thin layer of the material.

### SUMMARY

The systems, methods and devices of the disclosure each have several innovative aspects, no single one of which is solely responsible for the desirable attributes disclosed herein.

One innovative aspect of the subject matter described in this disclosure can be implemented in a method including moving a magnet assembly including a magnet element to sputter a material from a target onto a substrate. The target may be positioned between the magnet assembly and the substrate. The magnet assembly may move from a first position, across a portion of a face of the substrate, to a second position. The magnet assembly also may move from a third position with at least a portion of the magnet assembly being over the substrate proximate a second edge of the substrate, across the face of the substrate, to a fourth position with at least a portion of the magnet assembly being over the substrate proximate a first edge of the substrate. The first position, the second position, the third position, and the fourth position may be different positions.

Another innovative aspect of the subject matter described in this disclosure can be implemented in an apparatus including a magnet assembly including a magnet element, a substrate holder configured to hold a substrate, a target holder configured to hold a target positioned between the magnet assembly and the substrate, a motor configured to move the magnet assembly across a face of the substrate, and a controller including program instructions for conducting a process. The process may include moving the magnet assembly from a first position, across the face of the substrate, to a second position. Moving the magnet assembly from the first position to the second position may include moving the magnet assembly over a first edge of the substrate, across the substrate, and over a second edge of the substrate. The process also may include moving the magnet assembly from a third position with at least a portion of the magnet assembly being over the substrate proximate the second edge, across the face of the substrate, to a fourth position with at least a portion of the magnet assembly being over the substrate proximate the first position. The first position, the second position, the third position, and the fourth position may be different positions.

In some implementations, the motor may be a stepper motor. The controller may be configured to control the motor to move the magnet assembly to the first position, the second position, the third position, and the fourth position. In some implementations, the magnet assembly may be over the substrate proximate the second edge in the third position and over the substrate proximate the first edge in the fourth position. In some implementations, the controller may further include program instructions for applying a power to the magnet element.

Another innovative aspect of the subject matter described in this disclosure can be implemented in an apparatus including a magnet assembly including a magnet element, a substrate holder configured to hold a substrate, a target holder configured to hold a target positioned between the magnet assembly and the substrate, a motor configured to move the magnet assembly across a face of the substrate, and a controller including program instructions for conducting a process. The process may include moving the magnet assembly from a first position, across the face of the substrate, to a second position. The process also may include holding the magnet assembly in a third position over the substrate. The first position, the second position, and the third position may be different positions.

In some implementations, the motor may be a stepper motor. The controller may be configured to control the motor to move the magnet assembly to the first position, the second position, and the third position. In some implementations, the controller may further include program instructions for applying a power to the magnet element.

Another innovative aspect of the subject matter described in this disclosure can be implemented in a method including, in a first process chamber, moving a first magnet assembly including a first magnet element to sputter a material from a first target onto a substrate. The first target may be positioned between the first magnet assembly and the substrate. The first magnet assembly may move from a first position, over a first edge of the substrate, across a face of the substrate, and over a second edge of the substrate, to a second position. The substrate may be transferred from the first process chamber to a second process chamber. In the second process chamber, the second magnet assembly including a second magnet element may be moved to sputter a material from a second target onto the substrate. The second target may be positioned between the second magnet assembly and the substrate. The second magnet assembly may move from a third position with at least a portion of the second magnet assembly being over the substrate proximate the first edge, across the face of the substrate, to a fourth position with at least a portion of the second magnet assembly being over the substrate proximate the second edge. The first position, the second position, the third position, and the fourth position may be different positions.

In some implementations, the second magnet assembly may be over the substrate proximate the first edge in the third position and over the substrate proximate the second edge in the fourth position. In some implementations, the material sputtered from the first target and from the second target may form a layer of the material having a substantially uniform thickness on the substrate.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIGS. 9A and 9B show examples of schematic illustrations of a sputtering apparatus.

FIGS. 10A and 10B show examples of schematic illustrations of a sputtering apparatus.

FIG. 10C shows a cross-sectional schematic illustration of the thickness of a material deposited with the sputtering apparatus shown in FIGS. 10A and 10B.

FIGS. 11A and 11B show examples of schematic illustrations of a sputtering apparatus.

FIG. 11C shows a cross-sectional schematic illustration of the thickness of a material deposited with the sputtering apparatus shown in FIGS. 11A and 11B.

FIGS. 12A and 12B show examples of schematic illustrations of a sputtering apparatus.

FIG. 12C shows a cross-sectional schematic illustration of the thickness of a material deposited with the sputtering apparatus shown in FIGS. 12A and 12B.

FIGS. 13 and 14 show examples of flow diagrams illustrating manufacturing processes for sputter depositing a material having a substantially uniform thickness onto a substrate.

FIGS. 15A and 15B show examples of system block diagrams illustrating a display device that includes a plurality of interferometric modulators.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (for example, video) or stationary (for example, still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (for example, display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Some implementations described herein relate to physical vapor deposition apparatus and methods. For example, in some implementations, an apparatus may include a magnet assembly including a magnet element, a substrate holder configured to hold a substrate, a target holder configured to hold a sputter deposition target between the magnet assembly and the substrate, a motor configured to move the magnet assembly across a face of the substrate, and a controller. The controller may include program instructions for conducting a process, including instructions for moving the magnet assembly across the face of the substrate. The controller may further include instructions to apply a power to the magnet element. The magnet assembly may move from a first position, over a first edge of the substrate, across the face of the substrate, and over a second edge of the substrate, to a second position. The magnet assembly also may move from a third position with at least a portion of the magnet assembly being over the substrate proximate the second edge, across the face of the substrate, to a fourth position with at least a portion of the magnet assembly being over the substrate proximate the first position. The first position, the second position, the third position, and the fourth position may be different positions.

Particular implementations of the subject matter described in this disclosure can be implemented to realize one or more of the following potential advantages. Implementations of the apparatus and methods may be used to deposit a material having a substantially uniform thickness onto a surface of a substrate. A layer of material having a substantially uniform thickness on a surface of a substrate that is part of a device may result in better performance of the device. Overall yield improvements in manufacturing processes may be achieved with the apparatus and methods, lowering the costs of production of devices. The apparatus and methods may be used with substrates having a large surface area. For example, substrates may have a surface area of at least about 0.5 meters (m) by 0.5 m, in some implementations.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity. One way of changing the optical resonant cavity is by changing the position of the reflector.

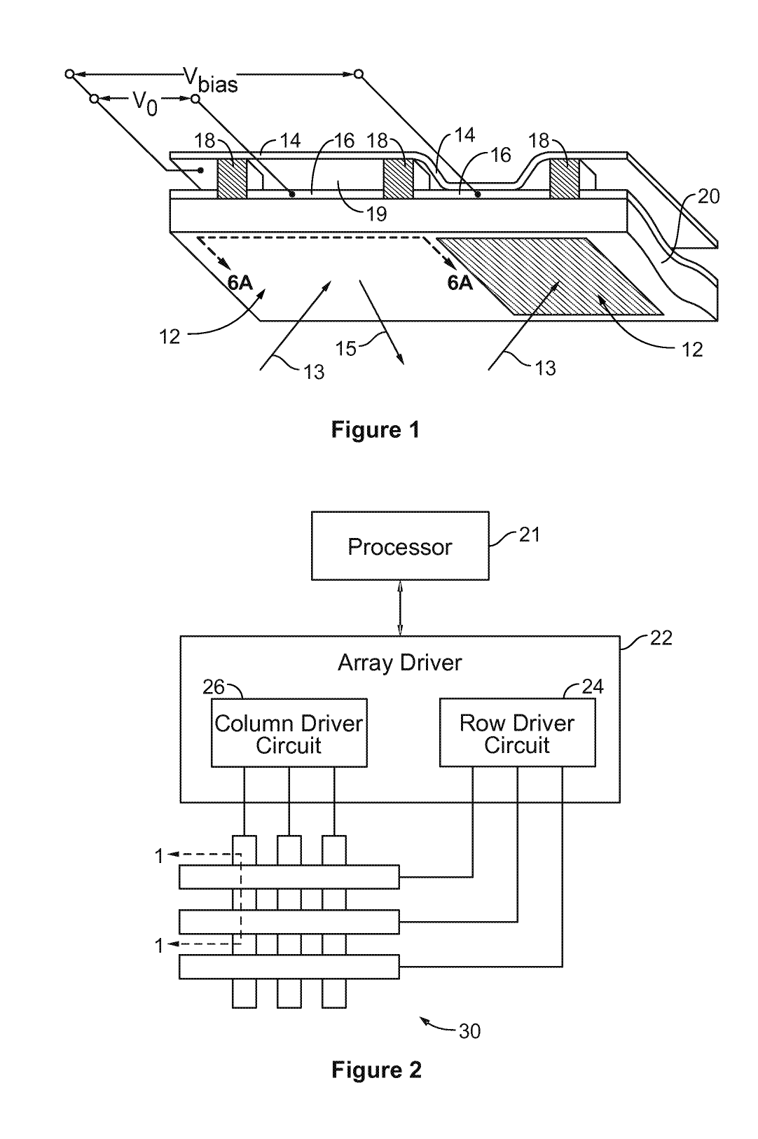

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, for example, to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, absorbing and/or destructively interfering light within the visible range. In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, such as chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and electrical conductor, while different, electrically more conductive layers or portions (for example, of the optical stack 16 or of other structures of the IMOD) can serve to bus signals between IMOD pixels. The optical stack 16 also can include one or more insulating or dielectric layers covering one or more conductive layers or an electrically conductive/optically absorptive layer.

In some implementations, the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than <10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, a voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example, a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

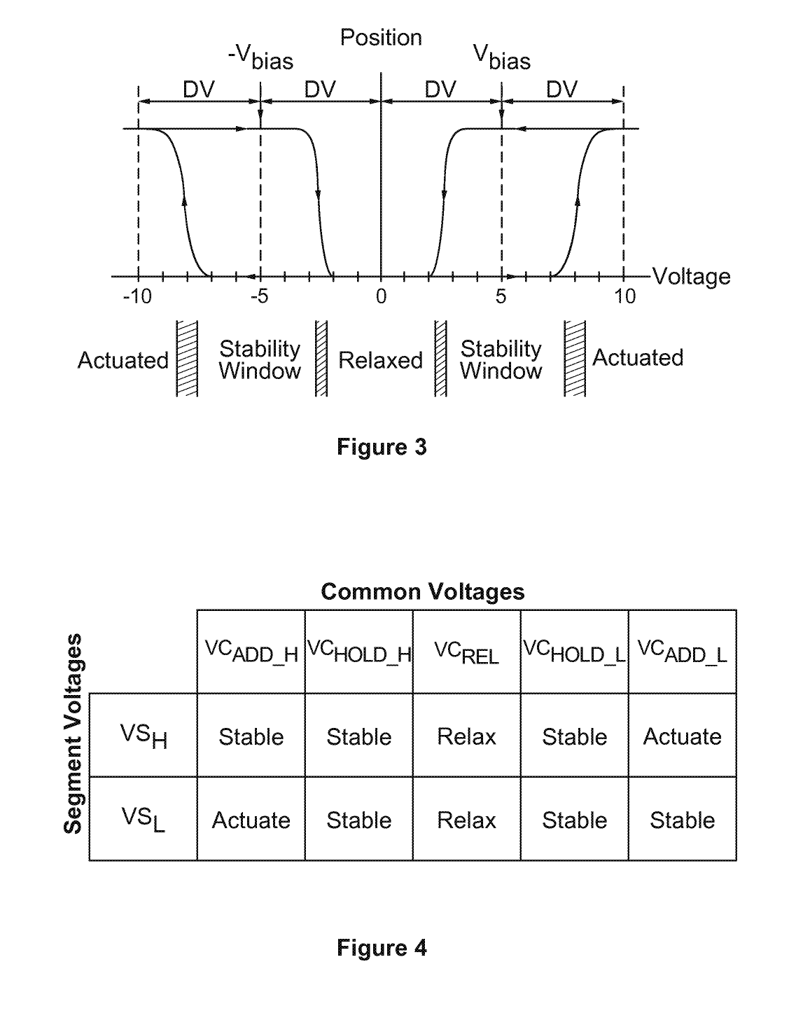

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may use, in one example implementation, about a 10-volt potential difference to cause the movable reflective layer, or mirror, to change from the relaxed state to the actuated state. When the voltage is reduced from that value, the movable reflective layer maintains its state as the voltage drops back below, in this example, 10 volts, however, the movable reflective layer does not relax completely until the voltage drops below 2 volts. Thus, a range of voltage, approximately 3 to 7 volts, in this example, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about, in this example, 10 volts, and pixels that are to be relaxed are exposed to a voltage difference of near zero volts. After addressing, the pixels can be exposed to a steady state or bias voltage difference of approximately 5 volts in this example, such that they remain in the previous strobing state. In this example, after being addressed, each pixel sees a potential difference within the “stability window” of about 3-7 volts. This hysteresis property feature enables the pixel design, such as that illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be understood by one having ordinary skill in the art, the “segment” voltages can be applied to either the column electrodes or the row electrodes, and the “common” voltages can be applied to the other of the column electrodes or the row electrodes.

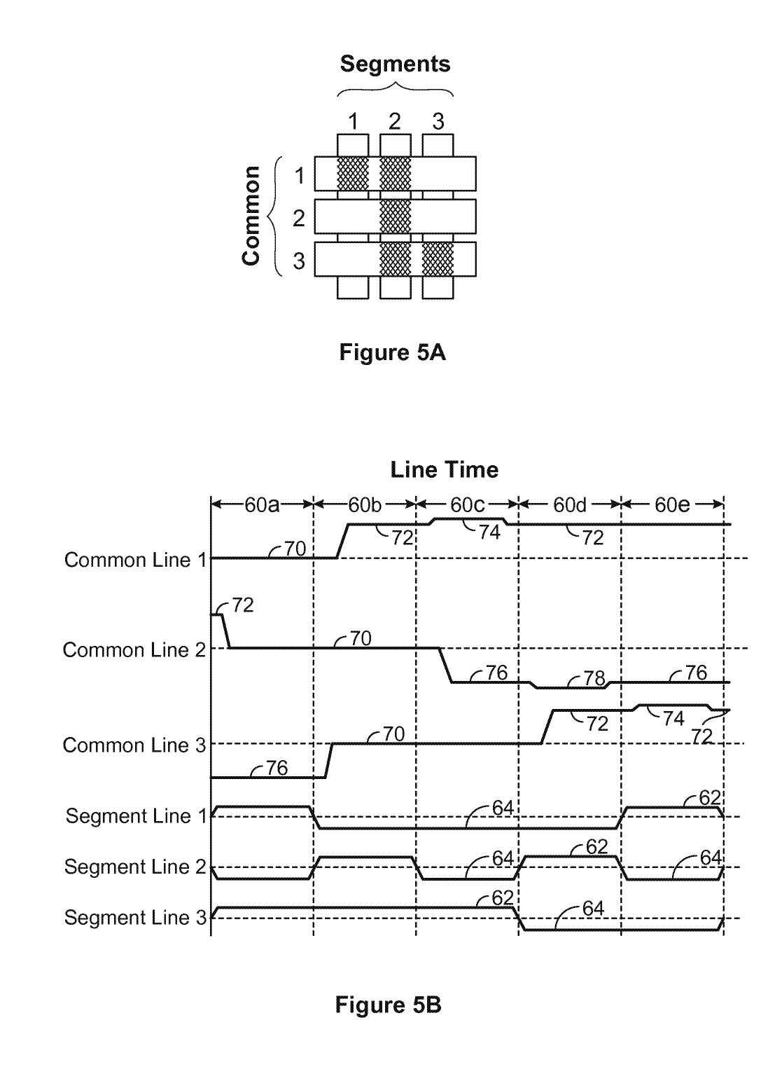

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator pixels (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators from time to time. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to a 3×3 array, similar to the array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, for example, a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

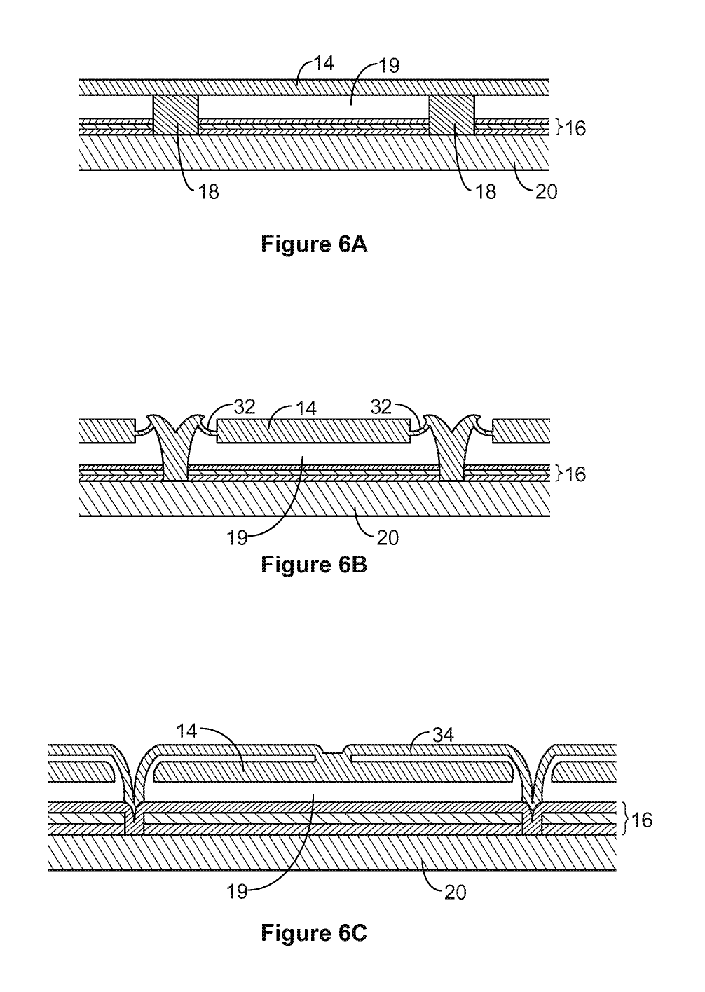

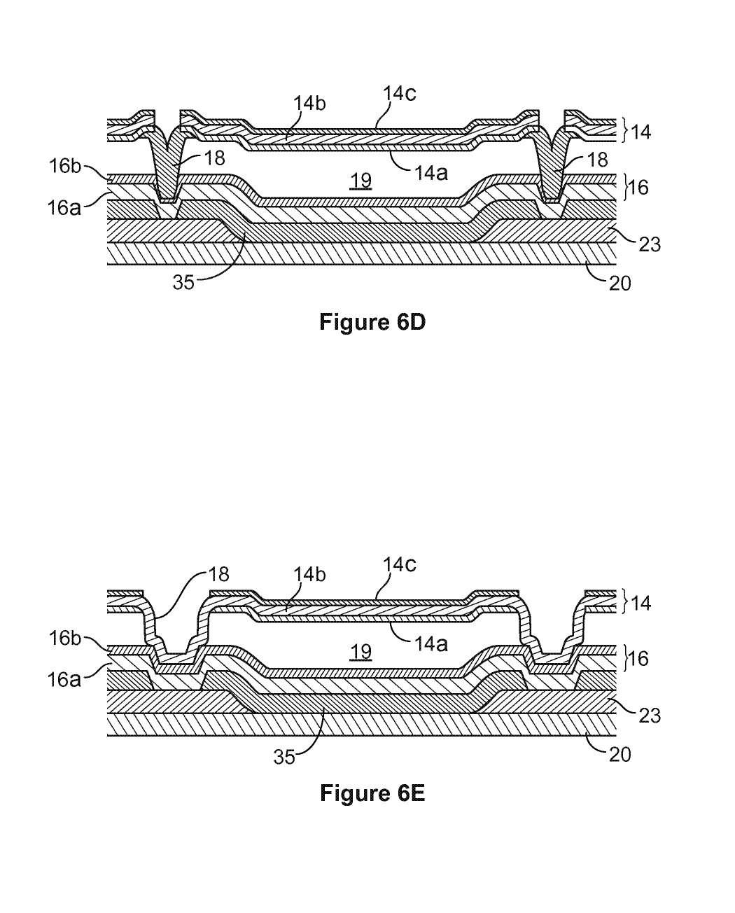

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, for example, an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (such as between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self-supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer. In some implementations, the optical absorber 16a is an order of magnitude (ten times or more) thinner than the movable reflective layer 14. In some implementations, optical absorber 16a is thinner than reflective sub-layer 14a.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, for example, patterning.

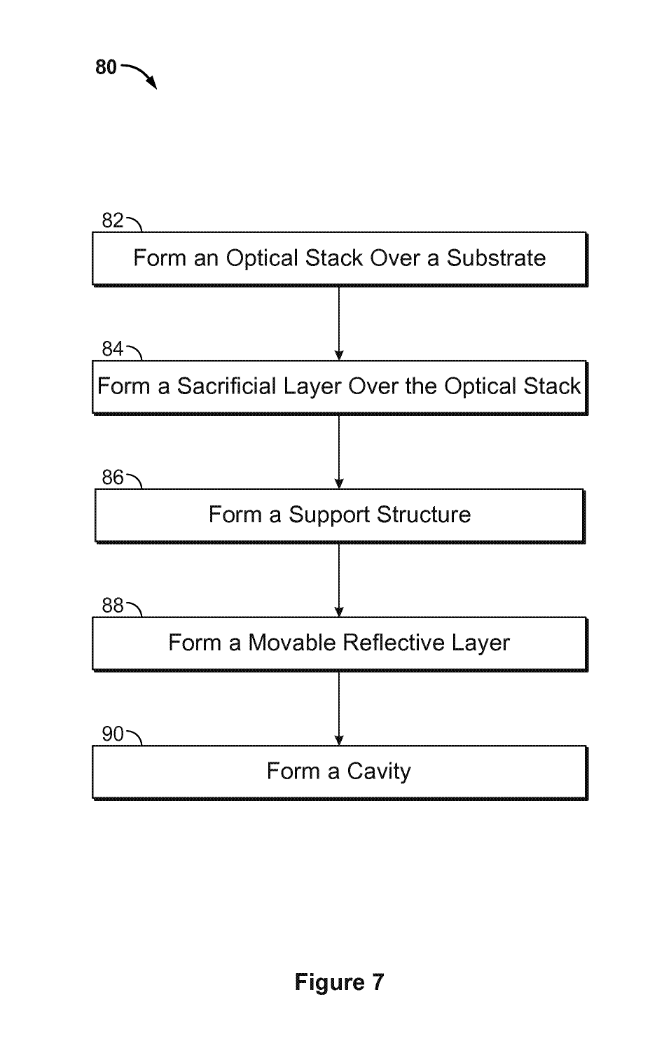

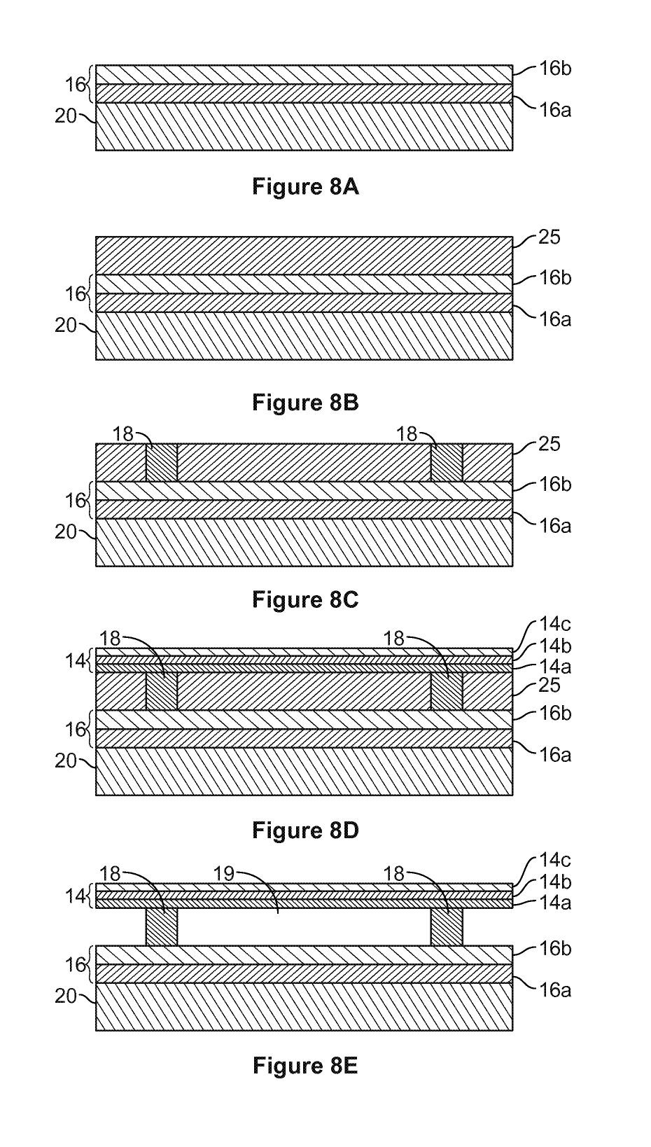

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture an electromechanical systems device such as interferometric modulators of the general type illustrated in FIGS. 1 and 6. The manufacture of an electromechanical systems device can also include other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, such as cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and electrically conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (for example, one or more reflective and/or conductive layers). In addition, the optical stack 16 can be patterned into individual and parallel strips that form the rows of the display. It is noted that FIGS. 8A-8E may not be drawn to scale. For example, in some implementations, one of the sub-layers of the optical stack, the optically absorptive layer, may be very thin, although sub-layers 16a, 16b are shown somewhat thick in FIGS. 8A-8E.

The process 80 continues at block 84 with the formation of a sacrificial layer 25 over the optical stack 16. The sacrificial layer 25 is later removed (see block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (a-Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, which includes many different techniques, such as sputtering), plasma-enhanced chemical vapor deposition (PECVD), thermal chemical vapor deposition (thermal CVD), or spin-coating. Since the size or height of the cavity 19 (see in FIGS. 1, 6 and 8E) depends upon the thickness of the deposited sacrificial material, improving the uniformity of deposition of the deposited sacrificial material can improve product quality be reducing variations across pixels and/or display devices being fabricated on the same substrate when compared to less uniform deposition techniques. In some implementations, scanning a magnet twice over a substrate in a PVD chamber, where each scan has different start and stop positions relative to the substrate can improve the uniformity of PVD deposition across a large area substrate, such as a large area glass substrate. Device performance can also benefit from improved uniformity for the deposition of layers other than the sacrificial layer.

The process 80 continues at block 86 with the formation of a support structure such as post 18, illustrated in FIGS. 1, 6 and 8C. The formation of the post 18 may include patterning the sacrificial layer 25 to form a support structure aperture, then depositing a material (such as a polymer or an inorganic material such as silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps including, for example, reflective layer (such as aluminum, aluminum alloy, or other reflective layer) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, such as cavity 19 illustrated in FIGS. 1, 6 and 8E. The cavity 19 may be formed by exposing the sacrificial material 25 (deposited at block 84) to an etchant. For example, an etchable sacrificial material such as Mo or a-Si may be removed by dry chemical etching, by exposing the sacrificial layer 25 to a gaseous or vaporous etchant, such as vapors derived from solid XeF₂, for a period of time that is effective to remove the desired amount of material. The sacrificial material is typically selectively removed relative to the structures surrounding the cavity 19. Other etching methods, such as wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

Material deposition during device fabrication, including fabrication of IMODs and other EMS devices, can involve sputtering. As noted above, sputtering is a PVD process. In some sputtering processes, ions of an inert gas from a plasma are accelerated towards a target of the material to be deposited. Atoms of the target are expelled from the target when the inert gas ions collide with the target. A portion of the atoms expelled from the target are collected on the surface of a substrate and form the thin layer of the target material on the substrate. Many different types of materials may be deposited with sputtering, including metals and ceramics.

One sputtering technique is magnetron sputtering. In magnetron sputtering, which is performed in a process chamber, a magnet or magnets included as part of a direct current (DC) diode device, referred to as a magnetron, may be positioned behind a target. The magnetic field produced by the magnetron may penetrate the target and magnetic field lines may form arcs over the target surface. This magnetic field may aid in confining electrons near the surface of the target. The electrons may undergo ionizing collisions with neutral sputtering gas atoms in the process chamber. The positively charged ions are accelerated toward the negatively biased target, and target material is sputtered from the target surface. Inert gasses, such as neon (Ne), argon (Ar), or krypton (Kr), may be used as the sputtering gas because inert gasses tend not to react with the target material or combine with any process gasses. Further, in some implementations, inert gasses also may produce higher sputtering and deposition rates due to their high molecular weights.

In some implementations of a magnetron sputtering apparatus, the magnet is movable using a motor for moving the magnet. For example, in some implementations, the target may be rectangular or square and the magnet may be scanned along a linear path with respect to the target. With such linear scan sputtering apparatus, a material may be deposited on a substrate having a large surface area. For example, a substrate having a large surface area may face a target having a large surface area, and the magnet may be scanned along a linear path with respect to the target and the substrate.

The thickness uniformity of the material deposited can be important in some sputtering processes. However, sputter depositing a material having a uniform thickness onto a large area substrate may be difficult in some instances. In some implementations, uniform-thickness deposition may be achieved on large area substrates by using large targets and linearly scanning the magnet assembly with respect to the target, producing uniform erosion of the target surface and a layer of material on the substrate.

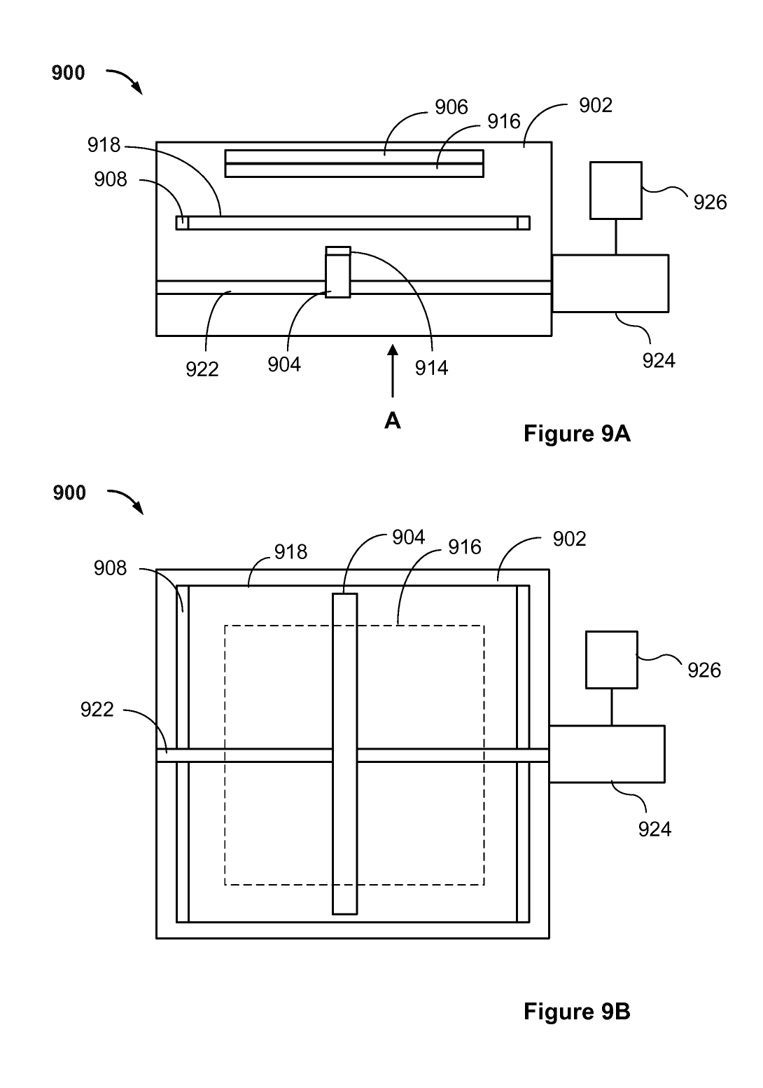

FIGS. 9A and 9B show examples of schematic illustrations of a sputtering apparatus. FIG. 9A shows an example of a cross-sectional schematic illustration of a sputtering apparatus 900. FIG. 9B shows an example of a schematic illustration of the sputtering apparatus 900 from a view point A in FIG. 9A. Although drawn in FIG. 9A as being on a bottom side of the sputtering apparatus 900, it is understood that view point A may also be on a top side of the sputtering apparatus 900, or on one of the sides of sputtering apparatus 900.

As shown in FIGS. 9A and 9B, the sputtering apparatus 900 includes a process chamber 902 including a magnet assembly 904, a substrate holder 906 configured to hold a substrate 916, and a target holder 908 configured to hold a target 918. The target 918 is positioned between the magnet assembly 904 and the substrate 916. In some implementations, the substrate 916 may have dimensions of at least about 0.5 meters (m) by 0.5 m. For example, the substrate 916 may have dimensions of about 0.5 m by 0.5 m to about 1.5 m by 1.5 m, or about 1 m by 1 m. In some implementations, the substrate 916 may be substantially rectangular or square. The substrate 916 may have any number of different shapes, however. In some implementations, the substrate 916 may be a glass (for example, a display glass or a borosilicate glass). In some implementations, the target 918 may have a larger surface area than the substrate 916. The target 918 includes the material to be sputtered onto the substrate 916, such as Mo, Al, or an Al alloy (for example, an aluminum copper (AlCu) alloy). Note that in FIG. 9B, the target 918 is over the substrate 916, and the substrate 916 is indicated by a dashed line.

The magnet assembly 904 includes one or more magnet elements 914. The magnet assembly 904 may be connected to a shaft 922 (for example, fixed on a bearing which may move along the shaft), with a motor 924 connected to the shaft 922 and configured to move the magnet assembly 904 across the face of the target 918. With the magnet assembly 904 moving across the face of the target 918, the magnet assembly 904 also moves across the face of the substrate 916, with the target 918 being positioned between the magnet assembly 904 and the substrate 916.

In some implementations, the magnet element 914 may have a width of about 110 millimeters (mm) to 135 mm or about 120 mm to 125 mm. In some implementations, the magnet element 914 may have a length of about 1100 mm to 1600 mm or about 1250 mm to 1440 mm. In some implementations, the magnet element 914 may have a thickness of about 25 mm to 45 mm or about 35 mm. The dimensions of the magnet element 914 may depend on the type of magnet included as part of the magnet element 914.

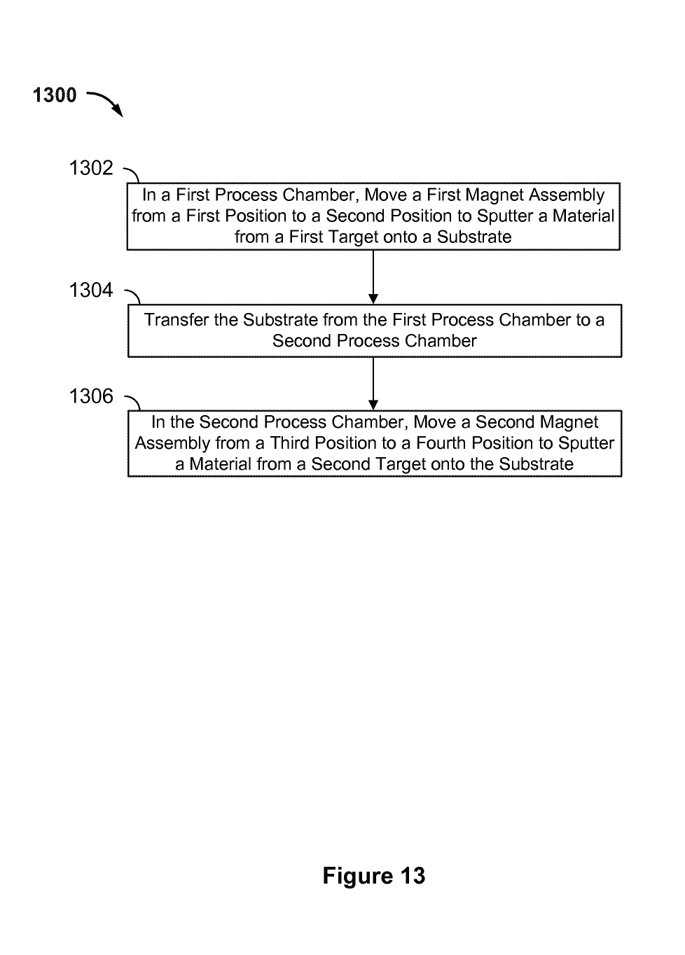

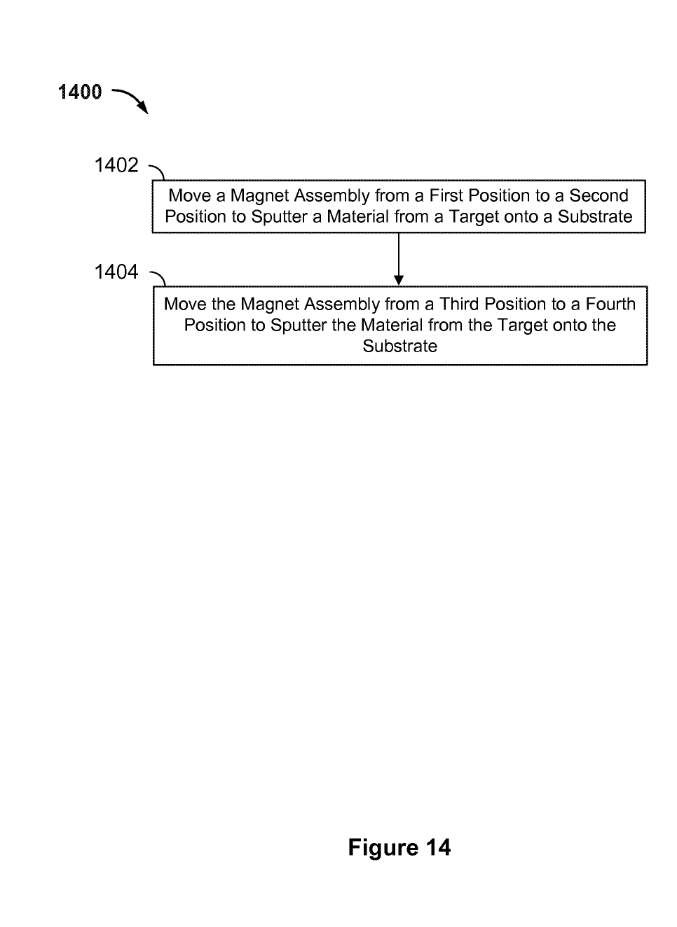

The sputtering apparatus 900 further includes a controller 926 which may include program instructions for conducting a manufacturing process in the sputtering apparatus 900. The process conditions and the process operations can be controlled by the controller 926. The process conditions and the process operations may include program instructions for monitoring, maintaining, and/or adjusting certain process variables, such as the pressure in the process chamber 902, the gas flow rates and times of gasses being admitted to the process chamber 902, the power/biases applied to different components of the sputtering apparatus 900, such as the power applied to the magnet elements 914, and the like. For example, program instructions specifying flow rates of argon for a sputtering process may be included. The program instructions may specify some or all of the parameters to perform operations according to the manufacturing processes described with respect to FIGS. 13 and 14, for example.

In some implementations, the controller 926 may include one or more memory devices and one or more processors configured to execute the program instructions so that the sputtering apparatus 900 can perform a method in accordance with the disclosed implementations. The processor may include a central processing unit (CPU) or a computer, analog and/or digital input/output connections, motor controller boards, and other like components. Program instructions for implementing appropriate process operations may be executed on or by the processor. These program instructions may be stored on the memory devices or other machine-readable media associated with the controller 926 or they may be provided over a network.

In some implementations, the controller 926 may control all or most of the operations of the sputtering apparatus 900. For example, the controller 926 may control all or most the operations of the sputtering apparatus 900 associated with sputtering a material. The controller 926 may execute system control software including sets of instructions for controlling the timing of the process operations, pressure levels, gas flow rates, and other parameters of particular manufacturing processes further described with respect to FIGS. 13 and 14. In some implementations, other computer programs, scripts, or routines stored on memory devices associated with the controller 926 may be employed.

In some implementations, a user interface may be associated with the controller 926. The user interface may include a display screen, graphical software to display process conditions, and user input devices such as pointing devices, keyboards, touch screens, microphones, and other like components.

In some implementations, the program instructions for controlling the operations of the sputtering apparatus 900 may include computer program code written in any conventional computer readable programming language, such as, for example, assembly language, C, C++, Pascal, Fortran, or others. Compiled object code or script may be executed by the processor of the controller 926 to perform the tasks identified in the program instructions.

In some implementations, signals for monitoring a manufacturing process may be provided by analog and/or digital input connections of the controller 926. Signals for controlling a manufacturing process may be output on analog and/or digital output connections of the controller 926.

In some implementations, the motor 924 may be a stepper motor. The controller 926 may be configured to control the velocity with which the magnet assembly 904 is driven by the motor 924 across the face of the target 918 and the face of the substrate 916 and the points at which the magnet assembly 904 starts and stops moving. That is, in some implementations, the motor 924 may be controlled by the controller 926, with the controller 926 configured to instruct the motor 924 to drive the magnet assembly 904 at specific velocities and to start and/or stop the magnet assembly 904 at different positions relative to the substrate 916. For example, the motor 924 may move the magnet assembly 904 at a velocity of about 180 millimeters per second (mm/s) to 300 mm/s. In some implementations, the sputtering apparatus 900 may include limit switches (not shown) that control the points at which the magnet assembly 904 starts and stops moving.

In some implementations, during a sputtering process, the process chamber 902 may contain a low pressure of Ar gas. For example, an Ar gas flow to the process chamber 902 may be about 25 standard cubic centimeters per minute (sccm) to 75 sccm, or about 50 sccm, yielding a process chamber pressure of about 0.1 pascals (Pa) to 0.3 Pa, or about 0.18 Pa.

In some implementations, the magnet assembly 904 may be linearly scanned across the face of the substrate 916. A power applied to the magnet element 914 of the magnet assembly 904 may form a plasma that is scanned across the face of the target 918 with the magnet assembly 904. For example, a power applied to the magnet element 914 of the magnet assembly 904 may be about 10 kilowatts (kW) to 65 kW. The average thickness of a layer of material deposited onto the substrate 916 may be about 100 Å to 120 Å with one scan of the magnet assembly 904 across the face of the substrate 916 with a power of about 55 kW applied to the magnet element 914; as used herein, one scan of the magnet assembly 904 includes the magnet assembly 904 traveling from left to right or from right to left across the face of the substrate 916. The thickness of a layer of material deposited onto the substrate 916 with one scan of the magnet assembly 904 can depend on a number of factors, including the velocity of the magnet assembly 904 (for example, a slower magnet assembly 904 velocity yields a thicker layer of material), the power applied to the magnet element 914, and the gas pressure in the process chamber 902. Multiple scans of the magnet assembly 904 may be performed to form a thicker layer of material on the substrate 916.

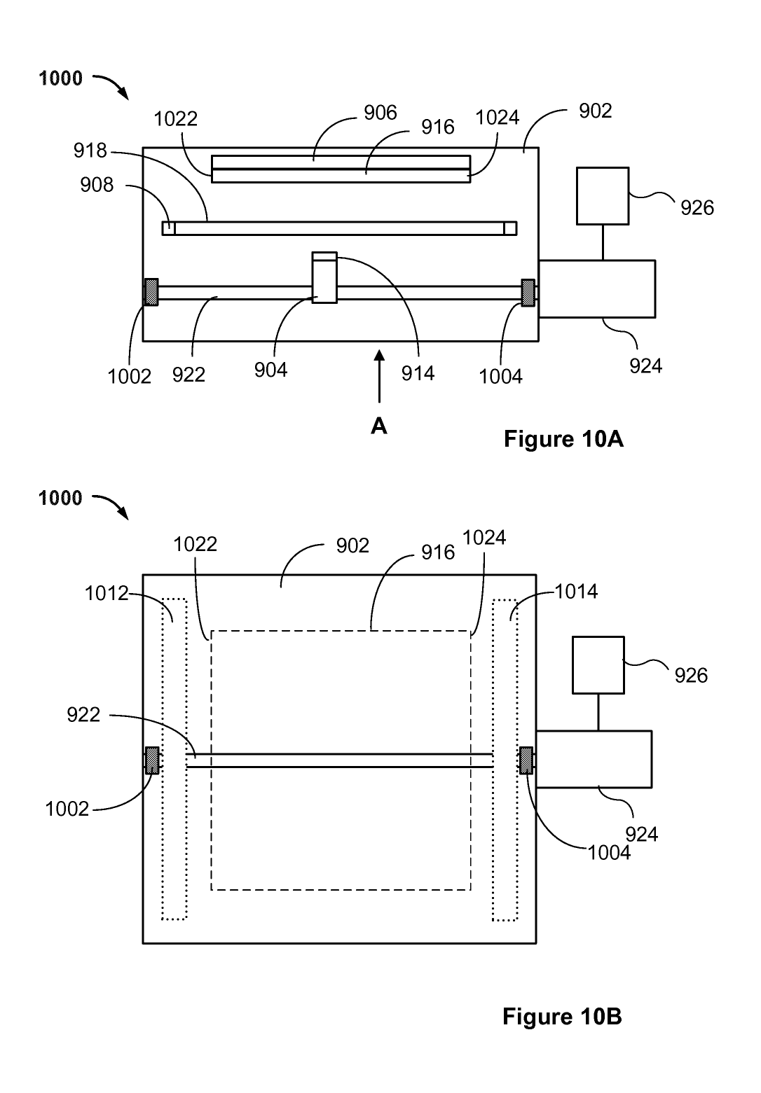

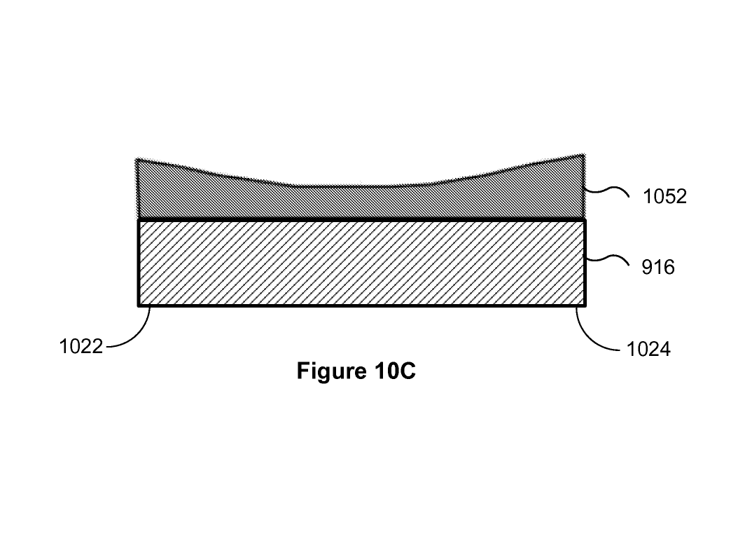

FIGS. 10A and 10B show examples of schematic illustrations of a sputtering apparatus. FIG. 10A shows an example of a cross-sectional schematic illustration of a sputtering apparatus 1000. FIG. 10B shows an example of a schematic illustration of the sputtering apparatus 1000 from a view point A in FIG. 10A, which can be a top, bottom, or side of the sputtering apparatus 1000. The sputtering apparatus 1000 shown in FIGS. 10A and 10B may be similar to the sputtering apparatus 900 shown in FIGS. 9A and 9B, with the addition of limit switches.

As shown in FIGS. 10A and 10B, the sputtering apparatus 1000 includes a process chamber 902 including a magnet assembly 904, a substrate holder 906 configured to hold a substrate 916, and a target holder 908 configured to hold a target 918. The magnet assembly 904 includes one or more magnet elements 914. The magnet assembly 904 may be connected to a shaft 922, with a motor 924 connected to the shaft 922 and configured to move the magnet assembly across the face of the substrate 916. The sputtering apparatus 1000 also may include a controller 926 which may include program instructions for conducting a process in the sputtering apparatus 1000. Note that some elements present in FIG. 10A, including the target holder 908, the target 918, and the magnet assembly 904 are omitted in FIG. 10B for clarity.

The sputtering apparatus 1000 also may include limit switches 1002 and 1004. In the sputtering apparatus 1000, the limit switches are positioned such that the magnet assembly 904 may travel linearly along the shaft 922 from a first position 1012 to a second position 1014, as indicated by the dashed outlines in FIG. 10B. The limit switch 1002 may define the first position 1012. For example, when the magnet assembly 904 is traveling from the second position 1014 to the first position 1012, the motor 924 may stop moving the magnet assembly 904 when the magnet assembly 904 reaches the limit switch 1002. The limit switch 1004 similarly may define the second position 1014. For example, when the magnet assembly 904 is traveling from the first position 1012 to the second position 1014, the motor 924 may stop moving the magnet assembly 904 when the magnet assembly 904 reaches the limit switch 1004. The magnet assembly 904 may stop moving at the limit switches 1002 and 1004 due to the switches being actuated and a signal being sent to the motor 924 or the controller 926 that stops the motor 924, for example. In some implementations, the limit switches 1002 and 1004 can include optical sensors for sensing the proximity of the magnet assembly 904.

In some implementations, in a sputtering process, the magnet assembly 904 may move from the first position 1012, over a first edge 1022 of the substrate 916, across the face of the substrate 916, and over a second edge 1024 of the substrate 916, to the second position 1014. In some implementations, about 50 microns to 150 microns, or about 100 microns, of material, may be deposited with a single scan of the magnet assembly 904. In some implementations, to deposit a thicker layer of material, the magnet assembly may move back from the second position 1014, over the second edge 1024 of the substrate 916, across the face of the substrate 916, and over the first edge 1022 of the substrate 916, to the first position 1012. In some other implementations, the magnet assembly 904 may be moved back to the first position 1012 without sputtering any material and material may be deposited by moving the magnet assembly 904 from the first position 1012 to the second position 1014.

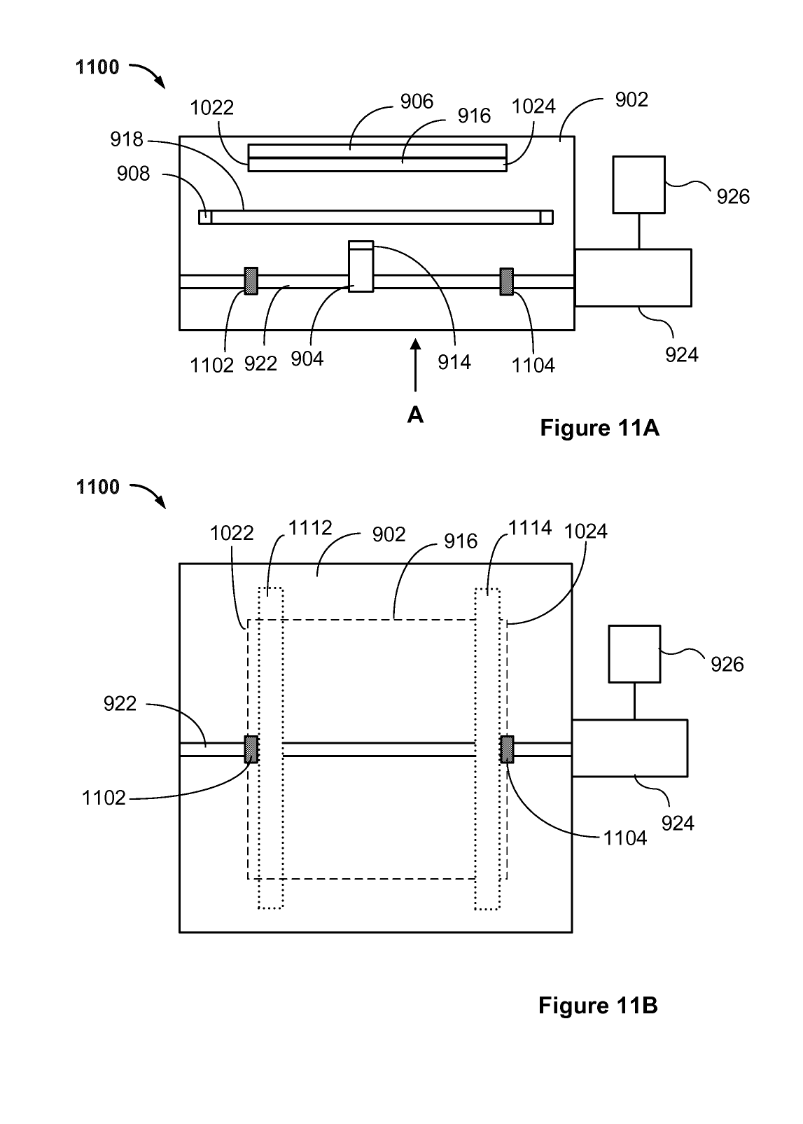

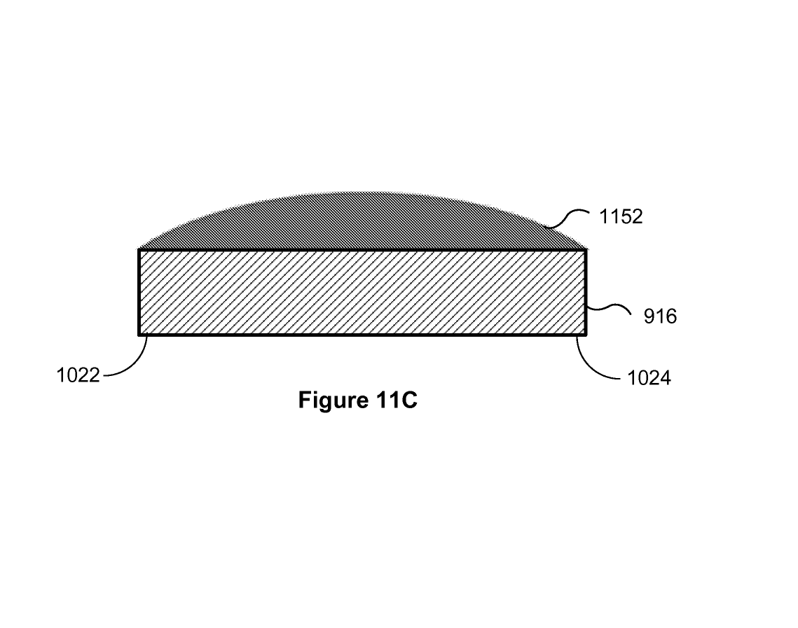

In the example shown in FIGS. 10A and 10B, in the first position 1012, the magnet assembly 904 is not positioned over the substrate 916 proximate the first edge 1022. Similarly, in the second position 1014, the magnet assembly 904 is not positioned over the substrate 916 proximate the second edge 1024. In some other implementations, all or part of the magnet assembly 904 can be positioned over the substrate 916 after reaching a limit switch. An example of such an implementation is described below with respect to FIGS. 11A and 11B.

In some implementations, the limit switches 1002 and 1004 may be electric switches that are actuated by a physical force (for example, the magnet assembly 904 contacting the limit switch) through the use of a tipping-point mechanism. In some implementations, a limit switch may switch reliably and at specific and repeatable positions of the actuator of the limit switch. In some implementations, a small movement at an actuator of a limit switch may produce a large movement at the electrical contacts of the limit switch. In some implementations, a sensor, such as an optical sensor, may be positioned to detect the position of the substrate 916 and send a signal to actuate a limit switch. In some implementations, a sensor may be associated each position and/or limit switch.

FIG. 10C shows a cross-sectional schematic illustration of the thickness of a material deposited with the sputtering apparatus 1000 shown in FIGS. 10A and 10B. That is, FIG. 10C shows the thickness profile of the material deposited onto the substrate 916 with the sputtering apparatus 1000. The substrate 916 has a layer of material 1052 disposed on it. As shown, the layer of material 1052 may not have a uniform thickness. The layer of material 1052 is thicker at the edges 1022 and 1024 of the substrate 916 than at the center of the substrate 916. For example, in some implementations, the thickness of a layer of an AlCu alloy or Mo may vary by about 30 Å to 50 Å from the edges of the substrate 916 to the center of the substrate 916. In some implementations, when multiple deposition scans using the sputtering apparatus 1000 are performed to deposit a desired thickness of material, the thickness of the layer of material 1052 may vary by over about 150 Å from the edges of the substrate 916 to the center of the substrate 916. The variation in the thickness of the deposited layer of material may vary with the thickness of the layer of material deposited. For example, the thickness of the layer of material 1052 may vary by over about 20% of the average thickness from the edges 1022 and 1024 of the substrate 916 to the center of the substrate 916.

FIGS. 11A and 11B show examples of schematic illustrations of a sputtering apparatus. FIG. 11A shows an example of a cross-sectional schematic illustration of a sputtering apparatus 1100. FIG. 11B shows an example of a schematic illustration of the sputtering apparatus 1100 from a view point A in FIG. 11A. A sputtering apparatus 1100 shown in FIGS. 11A and 11B may be similar to the sputtering apparatus 1000 shown in FIGS. 10A and 10B, with the limit switches being positioned differently.

As shown in FIGS. 11A and 11B, the sputtering apparatus 1100 includes a process chamber 902 including a magnet assembly 904, a substrate holder 906 configured to hold a substrate 916, and a target holder 908 configured to hold a target 918. The magnet assembly 904 includes one or more magnet elements 914. The magnet assembly 904 may be connected to a shaft 922, with a motor 924 connected to the shaft 922 and configured to move the magnet assembly across the face of the substrate 916. The sputtering apparatus 1100 also may include a controller 926 which may include program instructions for conducting a process in the sputtering apparatus 1100. Note that some elements present in FIG. 11A, including the target holder 908, the target 918, and the magnet assembly 904 are omitted in FIG. 11B for clarity.

The sputtering apparatus 1100 also may include limit switches 1102 and 1104. In the sputtering apparatus 1100, the limit switches are positioned such that the magnet assembly 904 may travel linearly along the shaft 922 from a third position 1112 to a fourth position 1114, as indicated by the dashed outlines in FIG. 11B. The limit switch 1102 may define the third position 1112. For example, when the magnet assembly 904 is traveling from the fourth position 1114 to the third position 1112, the motor 924 may stop moving the magnet assembly 904 when the magnet assembly 904 reaches the limit switch 1102. The limit switch 1104 similarly may define the fourth position 1114. For example, when the magnet assembly 904 is traveling from the third position 1112 to the fourth position 1114, the motor 924 may stop moving the magnet assembly 904 when the magnet assembly 904 reaches the limit switch 1104. The magnet assembly 904 may stop moving at the limit switches 1102 and 1104 due to the switches being actuated and a signal being sent to the motor 924 or the controller that stops the motor 924, for example.

In some implementations, in a sputtering process, the magnet assembly 904 may move from the third position 1112, across the face of the substrate 916, to the fourth position 1114. In some implementations, to deposit a thicker layer of material, the magnet assembly may move back from the fourth position 1114, across the face of the substrate 916, to the third position 1112. In some other implementations, the magnet assembly 904 may be moved back to the third position 1112 without sputtering any material and material may be deposited by moving the magnet assembly 904 from the third position 1112 to the fourth position 1114.

In some implementations, in the third position 1112, the magnet assembly 904 may be over the substrate 916 proximate the first edge 1022. In the fourth position 1114, the magnet assembly 904 may be over the substrate 916 proximate the second edge 1024. Such an implementation is shown in FIGS. 11A and 11B. In some other implementations, in the third position 1112, at least a portion of the magnet assembly 904 may be over the substrate 916 proximate the first edge 1022. In the fourth position 1114, at least a portion of the magnet assembly 904 may be over the substrate 916 proximate the second edge 1024.

In some implementations, the third position 1112 and the fourth position 1114 may be located close to one another or be substantially the same positions, with the magnet assembly 904 being over the substrate 916. For example, in some implementations, in a fifth position, the magnet assembly 904 may be over the substrate 916. In some implementations, in a sputtering process, the magnet assembly 904 may remain in the fifth position and not move from the fifth position.

FIG. 11C shows a cross-sectional schematic illustration of the thickness of a material deposited with the sputtering apparatus 1100 shown in FIGS. 11A and 11B. That is, FIG. 11C shows the thickness profile of the material deposited onto the substrate 916 with the sputtering apparatus 1100. The substrate 916 has a layer of material 1152 disposed on it. As shown, the layer of material 1152 may not have a uniform thickness. The layer of material 1152 is thicker at the center of the substrate 916 than at the edges 1022 and 1024 of the substrate 916.

In some implementations, the sputtering apparatus 1000 and the sputtering apparatus 1100 may be connected by a vacuum chamber. With such an apparatus, the sputtering apparatus 1000 could be used to deposit a material onto a substrate, and then the substrate could be transported, under vacuum in the vacuum chamber, to the sputtering apparatus 1100. Then, the sputtering apparatus 1100 could be used to deposit the material onto the substrate. In some implementations, combining the thicknesses of materials deposited with the sputtering apparatus 1000 and the sputtering apparatus 1100 may yield a layer of material having a substantially uniform thickness. In some implementations, the thickness variation of the layer of material deposited on a substrate with the sputtering apparatus 1000 and followed by the sputtering apparatus 1100 may be less than about 10% of the average thickness of the layer of material. In some implementations, deposition may occur in sputtering apparatus 1100 first, followed by sputtering apparatus 1000.

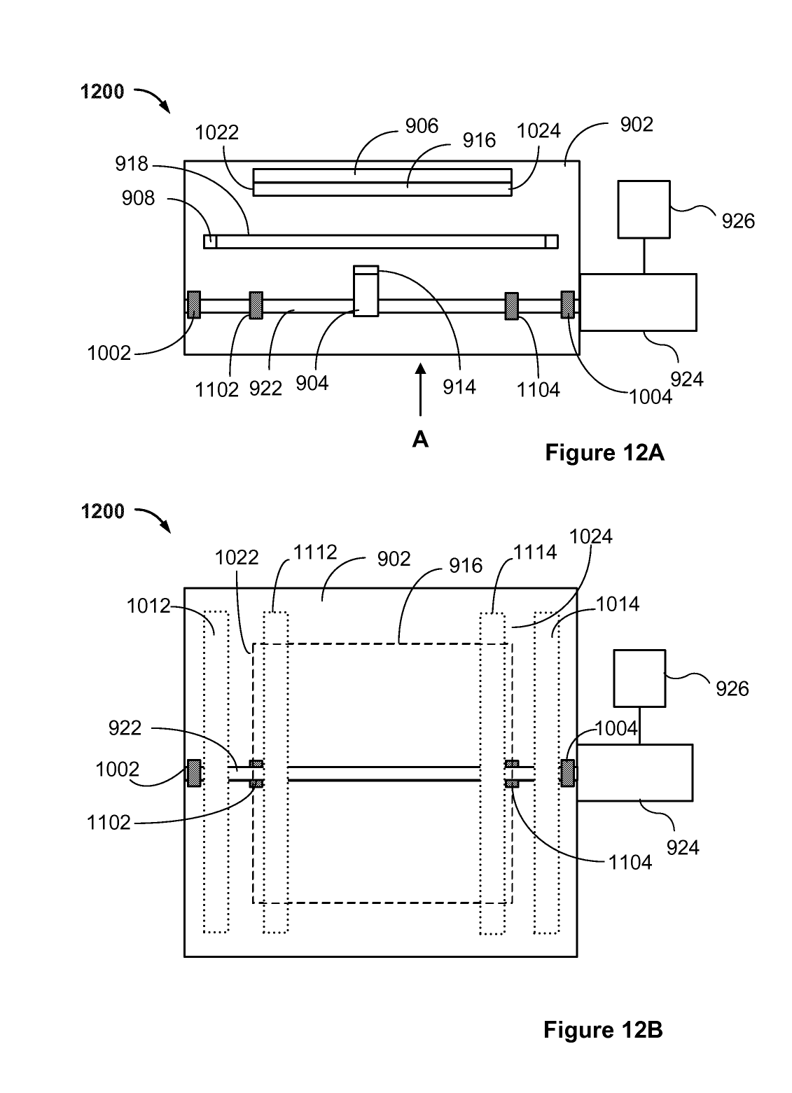

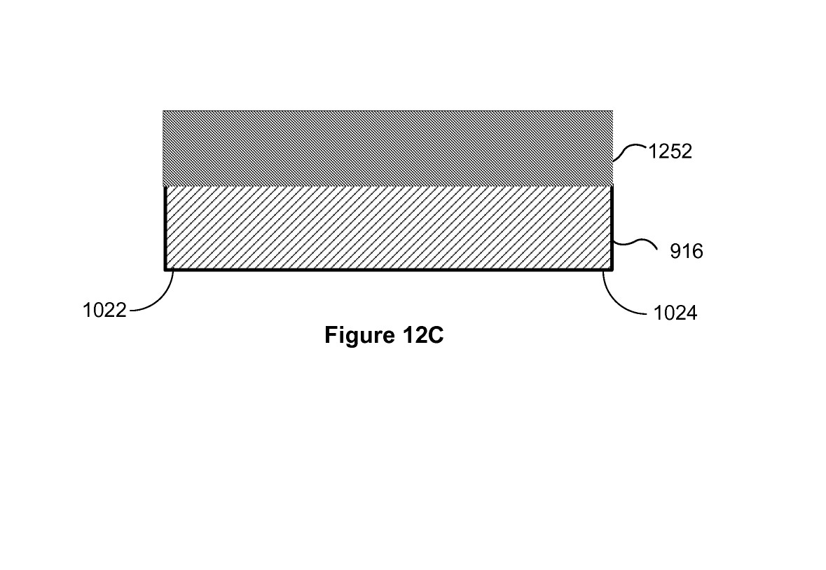

FIGS. 12A and 12B show examples of schematic illustrations of a sputtering apparatus. FIG. 12A shows an example of a cross-sectional schematic illustration of a sputtering apparatus 1200. FIG. 12B shows an example of a schematic illustration of the sputtering apparatus 1200 from a view point A in FIG. 12A. As shown in FIGS. 12A and 12B, the sputtering apparatus 1200 includes a process chamber 902 including a magnet assembly 904, a substrate holder 906 configured to hold a substrate 916, and a target holder 908 configured to hold a target 918. The magnet assembly 904 includes one or more magnet elements 914. The magnet assembly 904 may be connected to a shaft 922, with a motor 924 connected to the shaft 922 and configured to move the magnet assembly across the face of the substrate 916. The sputtering apparatus 1200 also may include a controller 926 which may include program instructions for conducting a process in the sputtering apparatus 1200. Note that some elements present in FIG. 12A, including the target holder 908, the target 918, and the magnet assembly 904 are omitted in FIG. 12B for clarity.

The sputtering apparatus 1200 also may include limit switches 1002, 1004, 1102 and 1104. In the sputtering apparatus 1200, the limit switches are positioned such that the magnet assembly 904 may travel linearly along the shaft 922 from a first position 1012 to a second position 1014 or from a third position 1112 to a fourth position 1114, as indicated by the dashed outlines in FIG. 12B. The limit switches 1002, 1004, 1102, and 1104 may define the first position 1012, the second position 1014, the third position 1112, and the fourth position 1114, respectively. For example, when the magnet assembly 904 is traveling from the fourth position 1114 to the third position 1112, the motor 924 may stop moving the magnet assembly 904 when the magnet assembly 904 reaches the limit switch 1102. The limit switch 1104 similarly may define the fourth position 1114. In another example, when the magnet assembly 904 is traveling from the second position 1014 to the first position 1012, the motor 924 may stop moving the magnet assembly 904 when the magnet assembly 904 reaches the limit switch 1102. The magnet assembly 904 may stop moving at any of limit switches 1002, 1004, 1102 or 1104, due to the switches being actuated and a signal being sent to the motor 924 or the controller that stops the motor 924, for example.

In some implementations, the limit switches 1002 and 1004 control a larger area scan, and the limit switches 1102 and 1104 control a smaller area scan. In some implementations, the limit switches 1002, 1004, 1102, and 1104 are all at fixed locations, with the locations described above with respect to FIGS. 10A-11B.

In some implementations, in a sputtering process, the magnet assembly 904 may move from the first position 1012, over a first edge 1022 of the substrate 916, across the face of the substrate 916, and over a second edge 1024 of the substrate 916, to the second position 1014. In some implementations, about 50 microns to 150 microns, or about 100 microns, of material, may be deposited with a single scan of the magnet assembly 904. In some implementations, to deposit a thicker layer of material, the magnet assembly may move back from the second position 1014, over the second edge 1024 of the substrate 916, across the face of the substrate 916, and over the first edge 1022 of the substrate 916, to the first position 1012. In some other implementations, the magnet assembly 904 may be moved back to the first position 1012 without sputtering any material and material may be deposited by moving the magnet assembly 904 from the first position 1012 to the second position 1014, after the initial scan between the first and second positions 1012, 1014.

In some implementations, the magnet assembly 904 may then move from the third position 1112, across the face of the substrate 916, to the fourth position 1114. In some implementations, to deposit a thicker layer of material, the magnet assembly may move back from the fourth position 1114, across the face of the substrate 916, to the third position 1112. In some other implementations, the magnet assembly 904 may be moved back to the third position 1112 without sputtering any material and material may be deposited by moving the magnet assembly 904 from the third position 1112 to the fourth position 1114, after the initial scan between the third and fourth positions 1112, 1114.

In sputtering processes in which the magnet assembly 904 may be moved between the first position 1012 and the second position 1014 and between the third position 1112 and the fourth position 1114, multiple scans between the first position 1012 and the second position 1014 may occur prior to multiple scans between the third position 1112 and the fourth position 1114, or scans between the between the first position 1012 and the second position 1014 may be interspersed with scans between the third position 1112 and the fourth position 1114.

According to various implementations, the magnet assembly 904 may be moved between any two positions. For example, in some implementations, the magnet assembly 904 may move between the first position 1012 and the third position 1112, and between the second position 1014 and the fourth position 1114.

FIG. 12C shows a cross-sectional schematic illustration of the thickness of a material deposited with the sputtering apparatus 1200 shown in FIGS. 12A and 12B. That is, FIG. 10C shows the thickness profile of the material deposited onto the substrate 916 with the sputtering apparatus 1200. The substrate 916 has a layer of material 1252 disposed on it. As shown, the layer of material 1052 may have a substantially uniform thickness. For example, the thickness of the layer of material 1252 may vary by less than about 10% of the average thickness from the edges 1022 and 1024 of the substrate 916 to the center of the substrate 916. The thickness profile in FIG. 12C may also be deposited with a sputtering apparatus that includes the sputtering apparatus 1000 and the sputtering apparatus 1100 connected by a vacuum chamber as described above.

FIGS. 13 and 14 show examples of flow diagrams illustrating manufacturing processes for sputter depositing a material having a substantially uniform thickness onto a substrate. A process 1300 as shown in FIG. 13 may be implemented using the sputtering apparatus 1000 and the sputtering apparatus 1100 connected by a vacuum chamber, for example.

Starting at block 1302 of the process 1300, in a first process chamber, a first magnet assembly may move from a first position to a second position to sputter a material from a first target onto a substrate. The first magnet assembly may include a first magnet element. The first target may be positioned between the first magnet assembly and the substrate. The first magnet assembly may move from the first position, over a first edge of the substrate, across a face of the substrate, and over a second edge of the substrate, to the second position. According to various implementations, the velocity of the magnet assembly in a single scan can be constant or non-constant. In some implementations, the magnet assembly may accelerate from rest at the beginning of a scan to a constant or non-constant velocity. In some implementations, the magnet may decelerate from a constant or non-constant velocity to rest at the end of a scan. In some implementations, the magnet assembly may accelerate or decelerate during some portion of the scan other than at the beginning or end of the scan.

The first magnet assembly may confine a first plasma at a surface of the first target during the sputtering process. In some implementations, the operation at block 1302 may be performed in a sputtering apparatus 1000 shown in FIGS. 10A and 10B.

At block 1304, the substrate may be transferred from the first process chamber to a second process chamber. In some implementations, the first process chamber may be similar to a sputtering apparatus 1000 shown in FIGS. 10A and 10B and the second process chamber may be similar to a sputtering apparatus 1100 shown in FIGS. 11A and 11B. In some implementations, a vacuum chamber may connect the first process chamber to the second process chamber so that the substrate may be transferred from the first process chamber to the second process chamber under vacuum or other controlled atmosphere.

At block 1306, in the second process chamber, a second magnet assembly may move from a third position to a fourth position to sputter a material from a second target onto the substrate. The second magnet assembly may include a second magnet element. The second target may be positioned between the second magnet assembly and the substrate. The second magnet assembly may move from the third position, across the face of the substrate, to the fourth position. In some implementations, relative to the substrate, three or more of the first position, the second position, the third position, and the fourth position are different positions. In some implementations, all of the first, second, third, and fourth positions are different positions relative to the substrate. In some implementations, the second magnet assembly may move in a substantially linear manner. The second magnet assembly may confine a second plasma at a surface of the second target during the sputtering process. In some implementations, the operation at block 1306 may be performed in a sputtering apparatus 1100 shown in FIGS. 11A and 11B.

In some implementations, in the third position, at least a portion of the second magnet assembly may be over the substrate proximate the first edge. In the fourth position, at least a portion of the second magnet assembly may be over the substrate proximate the second edge.

In some other implementations, in operation 1306, the third position and the fourth position may be located close to one another or be substantially the same positions, with the second magnet assembly being over the substrate. For example, in some implementations, in a fifth position, the second magnet assembly may be over the substrate. In some implementations, the second magnet assembly may not move from the fifth position during the sputtering process. The second magnet assembly may confine a second plasma at a surface of the second target during the sputtering process.

In some implementations, operations 1302 and 1306 of the manufacturing process 1300 may sputter deposit a material having a substantially uniform thickness onto the substrate. For example, in some implementations, operation 1302 may be performed one or more times and operation 1306 may be performed one or more times to sputter deposit a material having a substantially uniform thickness onto the substrate. In some implementations, sputtering a layer of material having a substantially uniform thickness onto a substrate may include a number of the operations 1302 and 1306, with about 90% to 95% of the operations being operation 1302 (i.e., moving the magnet assembly from the first position to the second position) or its counterpart of moving the magnet assembly from the second position to the first position and about 5% to 10% of the operations being operation 1306 (i.e., moving the magnet assembly from the third position to the fourth position) or its counterpart of moving the magnet assembly from the fourth position to the third position.

For example, in some implementations, the manufacturing process 1300 may be used to form a layer of material about 1000 Å thick by performing nine repetitions of operation 1302 and one operation of operation 1306. In some implementations, a layer of material about 1000 Å thick may vary by less than about 100 Å from the edges of the substrate to the center of the substrate.

In some implementations, to aid in depositing a uniform thickness of material, the sputtering conditions in operation 1302 and operation 1306 may be different. For example, in some implementations, the power applied to the magnet element of the first magnet assembly in operation 1302 may be higher or lower than the power applied to the magnet element of the second magnet assembly in operation 1306.

In some implementations, the order in which operations 1302 and 1306 are performed may not have an effect on the thickness uniformity of the deposited material. For example, in some implementations, operation 1306 may be performed before operation 1302. As another example, five repetitions of operation 1302, then one operation of operation 1306, and then four repetitions of operation 1302 may be performed, although this would entail the substrate being transferred back and forth between the process chambers. In some implementations, a process may include sputtering material in one or more additional process chambers, each of which may be configured to perform scans between one or more sets of positions as described above.

Turning to FIG. 14, a process 1400 may be implemented using the sputtering apparatus 900 having a stepper motor, for example. The process 1400 may be implemented using the sputtering apparatus 1200 depicted in FIGS. 12A and 12B, in another example. At block 1402 of the process 1400, a magnet assembly may move from a first position to a second position to sputter a material from a target onto a substrate. The magnet assembly may include a magnet element. The target may be positioned between the magnet assembly and the substrate. The magnet assembly may confine a plasma at a surface of the target during the sputtering process. The magnet assembly may move from the first position, over a first edge of the substrate, across a face of the substrate, and over a second edge of the substrate, to the second position. According to various implementations, the magnet assembly may move at a substantially constant or a non-constant velocity as described above. In some implementations, the magnet assembly also may move from the second position to the first position to sputter a material from the target onto the substrate. That is, the magnet assembly may move from the second position, over the second edge of the substrate, across the face of the substrate, and over the first edge of the substrate, to the first position. In some implementations, the magnet assembly moving from the first position to the second position may deposit a thickness of material having a certain thickness profile onto the substrate, and the magnet assembly moving from the second position to the first position may deposit a thickness of material having substantially the same thickness profile onto the substrate.

At block 1404, the magnet assembly may move from a third position to a fourth position to sputter a material from a target onto a substrate. The magnet assembly may move from the third position, across the face of the substrate, to the fourth position. In some implementations, relative to the substrate, three or more of the first position, the second position, the third position, and the fourth position are different positions. In some implementations, all of the first, second, third, and fourth positions are different positions relative to the substrate. In some implementations, the magnet assembly may move in a substantially linear manner. In some implementations, the magnet assembly also may move at a substantially constant velocity.

In some implementations, in the third position, at least a portion of the magnet assembly may be over the substrate proximate the first edge. In the fourth position, at least a portion of the magnet assembly may be over the substrate proximate the second edge. In some other implementations, in the third position, the magnet assembly may be over the substrate proximate the first edge. In the fourth position, the magnet assembly may be over the substrate proximate the second edge. In some implementations, the magnet assembly moving from the third position to the fourth position may deposit a thickness of material having a certain thickness profile onto the substrate, and the magnet assembly moving from the fourth position to the third position may deposit a thickness of material having substantially the same thickness profile onto the substrate.

In some other implementations, the third position and the fourth position may be located close to one another or be substantially the same positions, with the magnet assembly being over the substrate. For example, in some implementations, in a fifth position, the magnet assembly may be over the substrate. In some implementations, the magnet assembly may not move from the fifth position during the sputtering process. The magnet assembly may confine a plasma at a surface of the target during the sputtering process.

In some implementations, operations 1402 and 1404 together of the manufacturing process 1400 may sputter deposit a material having a substantially uniform thickness onto the substrate. For example, in some implementations, operation 1402 may be performed one or more times and operation 1404 may be performed one or more times to sputter deposit a material having a substantially uniform thickness onto the substrate. In some implementations, sputtering a layer of material having a substantially uniform thickness onto a substrate may include a number of the operations 1402 and 1404, with about 90% to 95% of the operations being operation 1402 (i.e., moving the magnet assembly from the first position to the second position) or its counterpart of moving the magnet assembly from the second position to the first position and about 5% to 10% of the operations being operation 1404 (i.e., moving the magnet assembly from the third position to the fourth position) or its counterpart of moving the magnet assembly from the fourth position to the third position. In some implementations, operations 1402 and 1404 are performed in a single chamber, for example, in a chamber having a motor and three, four, or more optical sensors to help control the motor where the system is capable of moving the magnet assembly so that one or more scans are performed between the first and second position and one or more other scans are performed between the third and fourth position, where three or more of the first, second, third, and fourth positions are all different positions relative to the substrate. In another single chamber implementation, the system is capable of moving the magnet assembly so that one or more scans are performed between the first and second position and one or more other scans are performed with the magnet assembly at a stationary fifth position, where the first, second, and fifth positions are all different positions relative to the substrate.

Similar to the manufacturing process 1300, in some implementations, to aid in depositing a uniform thickness of material, the sputtering conditions in operation 1402 and operation 1404 may be different. For example, in some implementations, the power applied to the magnet element of the magnet assembly in operation 1402 may be higher or lower than the power applied to the magnet element of the magnet assembly in operation 1404.

Again, similar to the manufacturing process 1300, in some implementations, the order in which operations 1402 and 1404 are performed may not have an effect on the thickness uniformity of the deposited material. For example, in some implementations, operation 1404 may be performed before operation 1402. As another example, five repetitions of operation 1402, then one operation of operation 1404, and then four repetitions of operation 1402 may be performed to deposit an about 1000 Å thick layer of material.

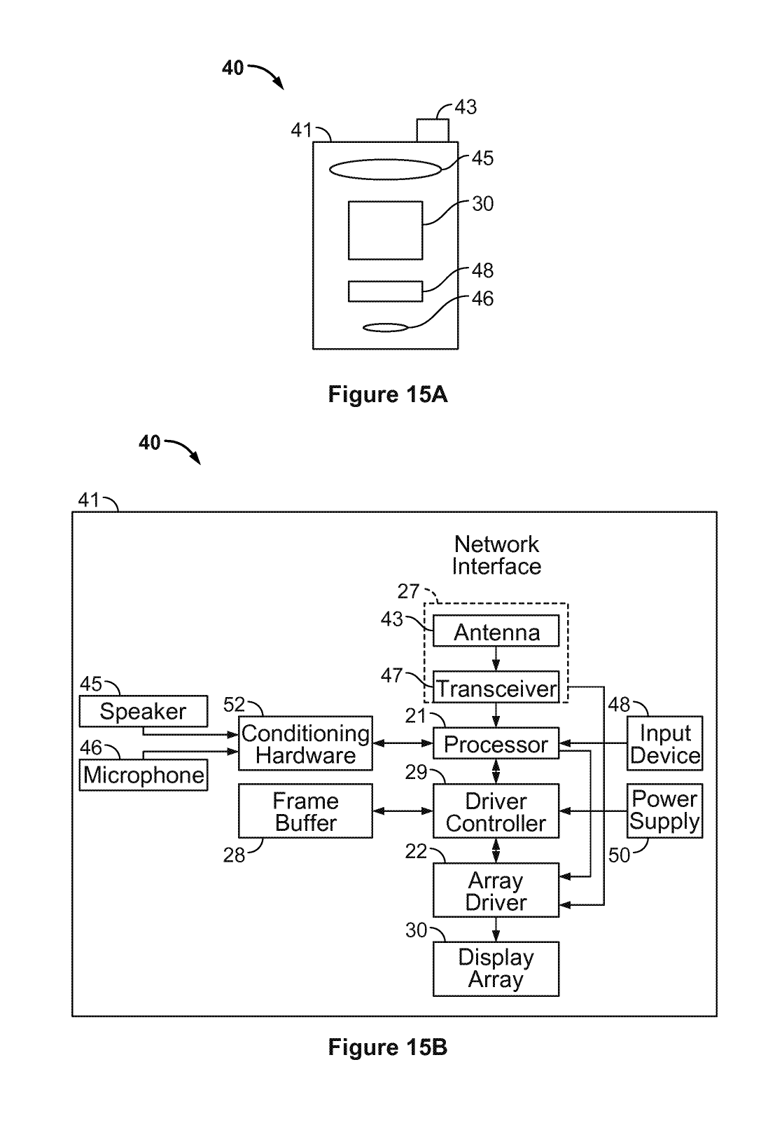

FIGS. 15A and 15B show examples of system block diagrams illustrating a display device 40 that includes a plurality of interferometric modulators. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players. The display device 40 can include one or more layers deposited in a PVD system similar to a PVD system as depicted in FIGS. 9A-12B, or according to the methods of FIGS. 13 and/or 14.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 15B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (for example, filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blue-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other possibilities or implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of an IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method comprising:
(a) moving a magnet assembly including a magnet element to sputter a material from a target onto a substrate having a first edge and a second edge, the target being positioned between the magnet assembly and the substrate, the magnet assembly moving from a first position, across the face of the substrate, to a second position; and
(b) moving the magnet assembly to sputter the material from the target onto the substrate, the magnet assembly moving from a third position with at least a portion of the magnet assembly being over the substrate proximate the second edge, across the face of the substrate, to a fourth position with at least a portion of the magnet assembly being over the substrate proximate the first edge, wherein the third position and the fourth position are both between the first position and the second position.

2. The method of claim 1, wherein the magnet assembly moves in operations (a) and (b) at a non-constant velocity.

3. The method of claim 1, wherein the magnet assembly moves in operations (a) and (b) at a substantially constant velocity.

4. The method of claim 1, wherein the material sputtered from the target in operations (a) and (b) forms a layer of the material having a substantially uniform thickness on the substrate.

5. The method of claim 1, wherein operation (a) includes moving the magnet assembly over a first edge of the substrate, across the entire face of the substrate, and over a second edge of the substrate.

6. The method of claim 1, further comprising:
(c) moving the magnet assembly to sputter the material from the target onto the substrate, the magnet assembly moving from the second position, over the second edge of the substrate, across the face of the substrate, and over the first edge of the substrate, to the first position.

7. The method of claim 6, further comprising:
repeating at least one of operations (a), (b), and (c) to sputter a layer of the material having a substantially uniform thickness onto the substrate, wherein about 90% to 95% of the operations include operations (a) and (c), and wherein about 5% to 10% of the operations include operation (b).

8. The method of claim 1, wherein the substrate is at least about 0.5 meters by 0.5 meters.

9. The method of claim 1, wherein the substrate is substantially rectangular.

10. The method of claim 1, wherein the magnet element of the magnet assembly confines a plasma at a surface of the target.

11. An apparatus comprising:
a magnet assembly including a magnet element;
a substrate holder configured to hold a substrate;
a target holder configured to hold a target positioned between the magnet assembly and the substrate;
a motor configured to move the magnet assembly across a face of the substrate; and
a controller including program instructions for conducting a process including:
(a) moving the magnet assembly from a first position, across the face of the substrate, to a second position; and
(b) moving the magnet assembly from a third position with at least a portion of the magnet assembly being over the substrate proximate the second edge, across the face of the substrate, to a fourth position with at least a portion of the magnet assembly being over the substrate proximate the first position, the first position, the second position, the third position, and the fourth position being different positions.

12. The apparatus of claim 11, wherein the motor is configured to move the magnet assembly in a substantially non-constant velocity.

13. The apparatus of claim 11, wherein the motor is configured to move the magnet assembly at a substantially constant velocity.

14. The apparatus of claim 11, wherein the motor is a stepper motor, and wherein the controller is configured to control the motor to move the magnet assembly to the first position, the second position, the third position, and the fourth position.

15. The apparatus of claim 11, wherein the magnet assembly is over the substrate proximate the second edge in the third position, and wherein the magnet assembly is over the substrate proximate the first edge in the fourth position.

16. The apparatus of claim 11, wherein the substrate is at least about 0.5 meters by 0.5 meters.

17. The apparatus of claim 11, wherein the magnet element of the magnet assembly is configured to confine a plasma at a surface of the target.

18. The apparatus of claim 11, wherein the controller further includes program instructions for applying a power to the magnet element during (a) and (b).

19. An apparatus comprising:
a magnet assembly including a magnet element;
a substrate holder configured to hold a substrate;
a target holder configured to hold a target positioned between the magnet assembly and the substrate;
a motor configured to move the magnet assembly across a face of the substrate; and
a controller including program instructions for conducting a process including:
(a) moving the magnet assembly from a first position, across the face of the substrate, to a second position; and
(b) holding the magnet assembly in a third position over the substrate, the first position, the second position, and the third position being different positions.

20. The apparatus of claim 19, wherein the motor is a stepper motor, and wherein the controller is configured to control the motor to move the magnet assembly to the first position, the second position, and the third position.

21. The apparatus of claim 19, wherein the magnet element of the magnet assembly is configured to confine a plasma at a surface of the target.

22. The apparatus of claim 19, wherein the controller further includes program instructions for applying a power to the magnet element during (a) and (b).

23. A method comprising:
(a) in a first process chamber, moving a first magnet assembly including a first magnet element to sputter a material from a first target onto a substrate, the first target being positioned between the first magnet assembly and the substrate, the first magnet assembly moving from a first position, over a first edge of the substrate, across a face of the substrate, and over a second edge of the substrate, to a second position; and
(b) transferring the substrate from the first process chamber to a second process chamber; and
(c) in the second process chamber, moving a second magnet assembly including a second magnet element to sputter a material from a second target onto the substrate, the second target being positioned between the second magnet assembly and the substrate, the second magnet assembly moving from a third position with at least a portion of the second magnet assembly being over the substrate proximate the first edge, across the face of the substrate, to a fourth position with at least a portion of the second magnet assembly being over the substrate proximate the second edge, the first position, the second position, the third position, and the fourth position being different positions.

24. The method of claim 23, wherein the first magnet assembly moves in operation (a) at a substantially constant velocity, and wherein the second magnet assembly moves in operation (c) at a substantially constant velocity.

25. The method of claim 23, wherein the second magnet assembly is over the substrate proximate the first edge in the third position, and wherein the magnet assembly is over the substrate proximate the second edge in the fourth position.

26. The method of claim 23, wherein the material sputtered from the first target in operation (a) and from the second target in operation (c) forms a layer of the material having a substantially uniform thickness on the substrate.

27. The method of claim 23, wherein operation (b) is performed using a vacuum chamber connecting the first process chamber to the second process chamber.

28. The method of claim 23, wherein the first magnet element of the first magnet assembly confines a first plasma at a surface of the first target, and wherein the second magnet element of the second magnet assembly confines a second plasma at a surface of the second target.
